(19) United States
(12) Patent Application Publication
(10) Pub. No.: US 2011/0308569 A1
(43) Pub. Date: Dec. 22, 2011

(54) MULTI-TERMINAL SOLAR PANEL

(75) Inventors: Hung-Chun TSAI, Hsinchu City (TW); Liang-Ji Chen, Taipei City (TW); Yu-Ting Lin, Hsinchu City (TW); Yaw-Ming Tsai, Taichung Hsien (TW); Ker-Tai Chu, Hong Kong (HK)

(73) Assignee: Du Pont Apollo Limited, Honk Kong (HK)

(21) Appl. No.: 13/163,732

(22) Filed: Jun. 20, 2011

Related U.S. Application Data
(60) Provisional application No. 61/356,660, filed on Jun. 21, 2010.

(51) Int. Cl. H01L 31/05

(52) U.S. Cl. 136/244

(57) ABSTRACT

A multi-terminal solar panel includes a first substrate, a first solar cell layer, a transparent intercellular layer, a second solar cell layer and a second substrate. The first solar cell layer is disposed on the first substrate and has a first bandgap. The first solar cell layer includes two first terminal outputs, arranged substantially in parallel with each other, at two opposite edges thereof. The transparent intercellular layer is disposed on the first solar cell layer and exposes the two first terminal outputs. The second solar cell layer is disposed on the transparent intercellular layer and has a second bandgap. The second solar cell layer includes two second terminal outputs, arranged substantially in parallel with each other, at two opposite edges thereof. The second substrate is disposed on the second solar cell layer, wherein the two second terminal outputs are substantially perpendicular to the two first terminal outputs.

### RELATED APPLICATIONS

This application claims priority to U.S. Provisional Application Ser. No. 61/356,660, filed Jun. 21, 2010, which is herein incorporated by reference.

### BACKGROUND

1. Field of Invention

The present invention relates to multi-terminal solar cell panel.

2. Description of Related Art

It is well known that the most efficient conversion of radiant energy to electrical energy with the least thermalization loss in semiconductor materials is accomplished by matching the photon energy of the incident radiation to the amount of energy needed to excite electrons in the semiconductor material to transcend the bandgap from the valence band to the conduction band. However, since solar radiation usually comprises a wide range of wavelengths, use of only one semiconductor material with one band gap to absorb such radiant energy and convert it to electrical energy results in large inefficiencies and energy losses to unwanted heat. Accordingly, the benefits of using tandem solar cells incorporating both wide bandgap and narrow bandgap materials have been recognized.

### SUMMARY

It is therefore an objective of the present invention to provide an improved multi-terminal solar panel.

In an aspect of the present invention, a multi-terminal solar panel includes a transparent first substrate, a first solar cell layer, a transparent intercellular layer, a second solar cell layer and an opaque second substrate. The first solar cell layer is disposed on the first transparent substrate and has a first bandgap. The first solar cell layer includes two first terminal outputs, arranged substantially in parallel with each other, at two opposite edges thereof. The transparent intercellular layer is disposed on the first solar cell layer and exposes the two first terminal outputs. The second solar cell layer is disposed on the transparent intercellular layer and has a second bandgap. The second solar cell layer includes two second terminal outputs, arranged substantially in parallel with each other, at two opposite edges thereof. The opaque second substrate is disposed on the second solar cell layer, wherein the two second terminal outputs are substantially perpendicular to the two first terminal outputs.

In another aspect of the present invention, a multi-terminal solar panel includes a transparent first substrate, a first solar cell layer, a transparent intercellular layer, a second solar cell layer and a transparent second substrate. The first solar cell layer is disposed on the first transparent substrate and has a first bandgap. The first solar cell layer includes two first terminal outputs, arranged substantially in parallel with each other, at two opposite edges thereof. The transparent intercellular layer is disposed on the first solar cell layer and exposes the two first terminal outputs. The second solar cell layer is disposed on the transparent intercellular layer and has a second bandgap. The second solar cell layer includes two second terminal outputs, arranged substantially in parallel with each other, at two opposite edges thereof. The transparent second substrate is disposed on the second solar cell layer, wherein the two second terminal outputs are substantially perpendicular to the two first terminal outputs.

According to an embodiment disclosed herein, the first bandgap is larger than or the same with the second bandgap.

According to another embodiment disclosed herein, the transparent intercellular layer has a breakdown voltage higher than 6000 V.

According to another embodiment disclosed herein, the transparent intercellular layer is an insulator to prevent oxygen and moisture from penetrating the intercellular layer.

According to another embodiment disclosed herein, the first solar cell layer comprises a p-i-n or p-n configuration in a direction from the first substrate to the second substrate.

According to another embodiment disclosed herein, the first solar cell layer comprises two transparent conductive layers, the p-i-n or p-n configuration is sandwiched between the two transparent conductive layers.

According to another embodiment disclosed herein, the second solar cell layer comprises a p-i-n, p-n, n-i-p or n-p configuration in a direction from the first substrate to the second substrate.

According to another embodiment disclosed herein, the second solar cell layer comprises two transparent conductive layers, the p-i-n, p-n, n-i-p or n-p configuration is sandwiched between the two transparent conductive layers.

According to another embodiment disclosed herein, the transparent intercellular layer comprises SiO, SiC, SiN, SiON, SiOC, or SiCN.

According to another embodiment disclosed herein, the transparent intercellular layer has a thickness ranging from about 1 nm to about 10 mm.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a perspective view of a multi-terminal solar panel according to an embodiment disclosed herein;

FIG. 2 illustrates a cross-sectional view of a multi-terminal solar panel according to an embodiment disclosed herein; and

FIG. 3 illustrates a cross-sectional view of a multi-terminal solar panel according to another embodiment disclosed herein.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

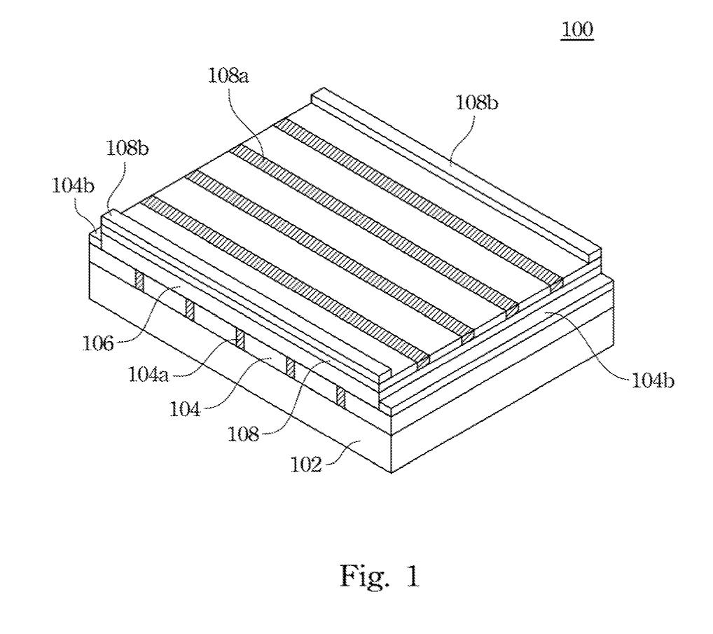

FIG. 1 illustrates a perspective view of a multi-terminal solar panel according to an embodiment disclosed herein. For easily illustrating the features of this multi-terminal solar panel, a back sheet or back glass is omitted in this figure. The solar panel 100 includes two independently-operated solar cell layers 104 and 108 on single side of its substrate 102 such that the solar panel 100 is more easily fabricated than a solar panel with its two independently-operated solar cell layers on two opposite sides of the substrate. In this embodiment, two solar cell layers 104 and 108 are separated by a transparent intercellular layer 106. The transparent intercellular layer 106 can be a layer with a breakdown voltage higher than 6000 V or an insulator to prevent oxygen and moisture from penetrating the intercellular layer. In an embodiment, two solar cell layers 104 and 108 may have respective bandgaps, e.g. the solar cell layer 104 has a larger bandgap while the solar cell layer 108 has a smaller bandgap, so as to efficiently convert radiant energy into electrical energy with the least thermalization loss. In an alternate embodiment, two solar cell layers 104 and 108 may have the same bandgaps. Each solar cell layer has several laser scribing trenches, e.g. 104a and 108a, to properly insulate its separate parts. In order to separately collect electrical currents from the solar cell layers 104 and 108 and avoid the current matching issues, the terminal outputs are specially arranged. In particular, the solar cell layer 104 has its two terminal outputs 104b, which are substantially in parallel with other and disposed at two opposite edges thereof. The intercellular layer 106 is deposited over the solar cell layer 104 and exposes the two terminal outputs 104b. The solar cell layer 108 has its two terminal outputs 108b which are substantially in parallel with other and disposed at two opposite edges thereof. Basically, the four terminal outputs 104a and 108b are arranged at four edges of the rectangular panel, respectively. That is, the terminal outputs 104b are substantially perpendicular with the terminal outputs 108b. With this regard, electrical currents of the solar cell layers 104 and 108 can be collected independently. In an alternate embodiment, the terminal outputs 104b can be also substantially in parallel with the terminal outputs 108b according to the designs as long as electrical currents of the solar cell layers 104 and 108 can be collected independently.

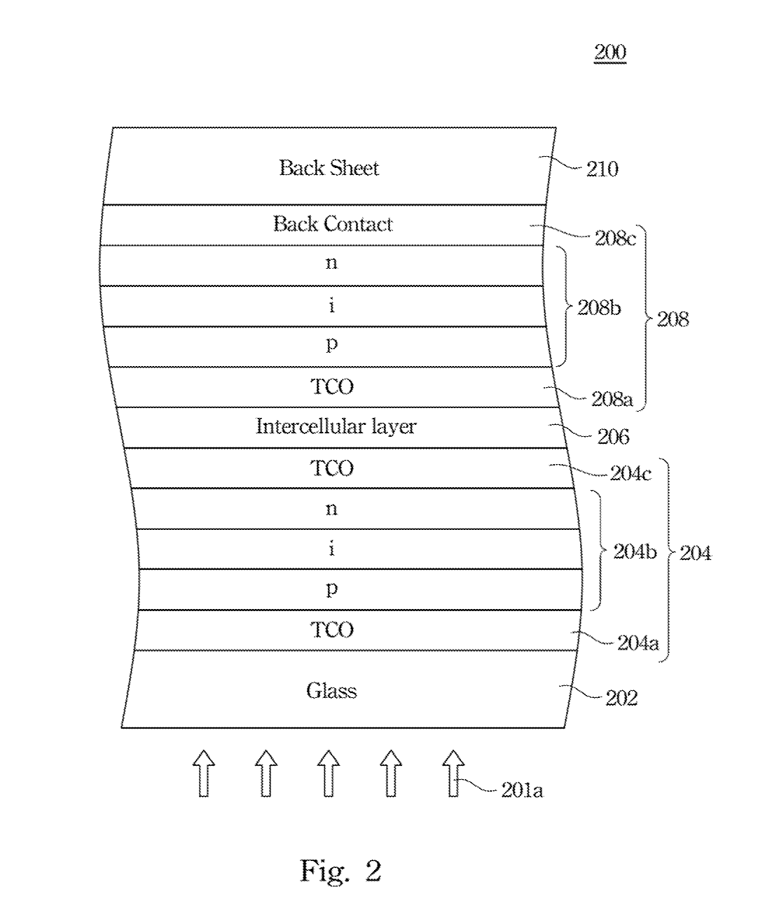

FIG. 2 illustrates a cross-sectional view of a multi-terminal solar panel according to an embodiment disclosed herein. In this figure, the laser scribing trenches, e.g. 104a and 108a as illustrated in FIG. 1, are omitted for clarity. In this embodiment, the solar panel 200 has its two solar cell layers 204 and 208 sandwiched between a glass substrate 202 and a back sheet 210 (e.g. an opaque substrate), and separated by an intercellular layer 206. Alternatively, the solar panel 200 further comprises an encapsulant sheet, such as EVA (ethylene vinyl acetate) or PVB (polyvinyl butyral), between the back sheet 210 and the back contact 208c. The intercellular layer 206 can be thin film layer made from SiO, SiC, SiN, SiON, SiOC, or SiCN, or a double layer or multi-layer made from above-mentioned materials. The intercellular layer 206 can be fabricated with a thickness ranging from about 1 nm to about 10 mm. The solar panel 200 is used with the transparent glass substrate 202 facing the solar radiation 201a. The solar cell layer 204 includes a p-i-n configuration 204b sandwiched between two transparent conductive layers (e.g. transparent conductive oxides 204a and 204c). The p-i-n configuration 204b is arranged in the direction from the glass substrate 202 to the back sheet 210, which has a better efficiency of converting solar radiation into electricity than a p-i-n configuration in the direction from the back sheet 210 to the glass substrate 202. In an alternate embodiment, the solar cell layer 204 includes a p-n configuration in the direction from the glass substrate 202 to the back sheet 210 according to the designs. The transparent conductive oxides 204a and 204c are electrically connected to their respective terminal outputs. For example, please refer to both FIG. 1 and FIG. 2, the terminal outputs 104b are electrically connected to the transparent conductive oxide 204c and at the two opposite edges of the transparent conductive oxide 204c. In other words, the two terminal outputs 104b disposed at the two opposite edges of the transparent conductive oxide 204c are anode and cathode, respectively. The solar cell layer 208 includes a p-i-n configuration 208b sandwiched between two conductive layers (e.g. a transparent conductive oxide 208a and a back contact 208c). The p-i-n configuration 208b is arranged in the direction from the glass substrate 202 to the back sheet 210, which has a better efficiency of converting solar radiation into electricity than a p-i-n configuration in the direction from the back sheet 210 to the glass substrate 202. In alternate embodiment, the solar cell layer 208 includes a p-n, n-i-p or n-p configuration in the direction from the glass substrate 202 to the back sheet 210 according to the designs. The p-i-n configuration 204b and 208b can be made from Si-based materials, CIGS, CdTe, Organic materials or DSSC materials. The transparent conductive oxide 208a and back contact 208c are electrically connected to their respective terminal outputs. For example, please refer to both FIG. 1 and FIG. 2, the terminal outputs 108b are electrically connected to the transparent conductive oxide 208a or hack contact 208c and at the two opposite edges of the transparent conductive oxide 208a or back contact 208c. In other words, the two terminal outputs 108b disposed at the two opposite edges of the transparent conductive oxide 208a or back contact 208c are anode and cathode, respectively.

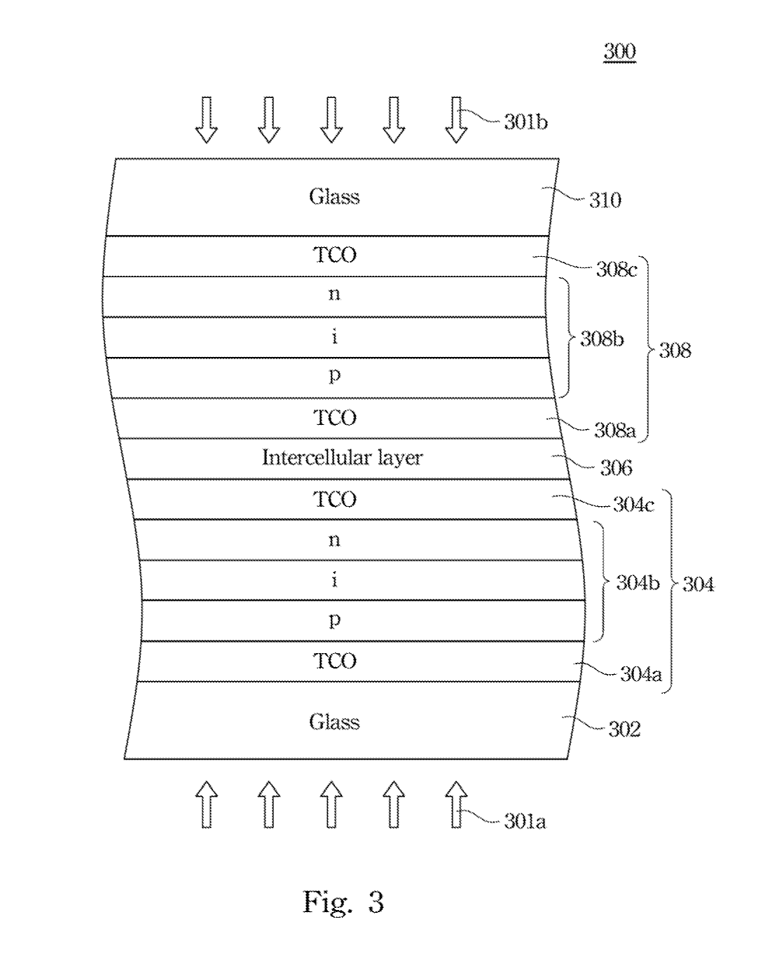

FIG. 3 illustrates a cross-sectional view of a multi-terminal solar panel according to an embodiment disclosed herein. In this figure, the laser scribing trenches, e.g. 104a and 108a as illustrated in FIG. 1, are omitted for clarity. This embodiment is different from the embodiment as illustrated in FIG. 2 in that the back sheet 210 is replaced by a glass substrate 310. In this embodiment, the solar panel 300 has its two solar cell layers 304 and 308 sandwiched between two transparent glass substrates 302 and 310, and separated by an intercellular layer 306. Since the two glass substrates 302 and 310 are transparent, the solar panel can absorb solar radiation 301a and 301b from two opposite sides. The intercellular layer 306 can be thin film layer made from SiO, SiC, SiN, SiON, SiOC, or SiCN, or a double layer or multi-layer made from above-mentioned materials. The intercellular layer 306 can be fabricated with a thickness ranging from 1 nm to 10 mm. The solar cell layer 304 includes a p-i-n configuration 304b sandwiched between two transparent conductive layers (e.g. transparent conductive oxides 304a and 304c). The p-i-n configuration 304b is arranged in the direction from the glass substrate 302 to the glass substrate 310, which has a better efficiency of converting solar radiation into electricity than a p-i-n configuration in the direction from the glass substrate 310 to the glass substrate 302. In an alternate embodiment, the solar cell layer 304 includes a p-n configuration in the direction from the glass substrate 302 to the glass substrate 310 according to the designs. The transparent conductive oxides 304a and 304c are electrically connected to their respective terminal outputs. For example, please refer to both FIG. 1 and FIG. 3, the terminal outputs 104h are electrically connected to the transparent conductive oxide 304a and at the two opposite edges of the transparent conductive oxide 304c. In other words, the two terminal outputs 104b at the two opposite edges of the transparent conductive oxide 304c are anode and cathode, respectively. The solar cell layer 308 includes a p-i-n configuration 308b sandwiched between two conductive layers (e.g. transparent conductive oxides 308a and 308c). In this embodiment, the p-i-n configuration 308b is arranged in the direction from the glass substrate 302 to the glass substrate 310 for more easy integration, production and other consideration. In an alternate embodiment, the solar cell layer 308 includes a p-n, n-i-p or n-p configuration in the direction from the glass substrate 302 to the glass substrate 310 according to the designs. The p-i-n configuration 304b and 308b can be made from Si-based materials, CIGS, CdTe, Organic materials or DSSC materials. The transparent conductive oxides 308a and 308c are electrically connected to their respective terminal outputs. For example, please refer to both FIG. 1 and FIG. 3, the terminal outputs 108b are electrically connected to the transparent conductive oxides (308a, 308c) and at the two opposite edges of the transparent conductive oxides (308a, 308c). In other words, the terminal outputs 108b disposed at the two opposite edges of the transparent conductive oxides (308a, 308c) are anode and cathode, respectively.

The terms “substantially” as used herein may be applied to modify any quantitative representation which could permissibly vary without resulting in a change in the basic function to which it is related.

According to the discussed embodiments, the solar panel includes two solar cell layers separated by a transparent intercellular layer. A first solar cell layer includes two first terminal outputs, arranged substantially in parallel with each other, at two opposite edges thereof. A second solar cell layer includes two second terminal outputs, arranged substantially in parallel with each other, at two opposite edges thereof. The two second terminal outputs are substantially perpendicular to the two first terminal outputs such that electrical currents of the first and second solar cell layers can be collected separately.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-terminal solar panel comprising:
a transparent first substrate;
a first solar cell layer disposed on the first substrate and having a first bandgap, the first solar cell layer comprising two first terminal outputs, arranged substantially in parallel with each other, at two opposite edges thereof;
a transparent intercellular layer disposed on the first solar cell layer and exposing the two first terminal outputs;
a second solar cell layer disposed on the transparent intercellular layer and having a second bandgap, the second solar cell layer comprising two second terminal outputs, arranged substantially in parallel with each other, at two opposite edges thereof; and
an opaque second substrate disposed on the second solar cell layer,
wherein the two second terminal outputs are substantially perpendicular to the two first terminal outputs.

2. The solar panel of claim 1, wherein the first bandgap is larger than or the same with the second bandgap.

3. The solar panel of claim 1, further comprising an encapsulant sheet between the second solar cell layer and the opaque second substrate.

4. The solar panel of claim 1, wherein the transparent intercellular layer is an insulator to prevent oxygen and moisture from penetrating the transparent intercellular layer.

5. The solar panel of claim 1, wherein the first solar cell layer comprises a p-i-n or p-n configuration in a direction from the first substrate to the second substrate.

6. The solar panel of claim 5, wherein the first solar cell layer comprises two transparent conductive layers, the p-i-n or p-n configuration is sandwiched between the two transparent conductive layers.

7. The solar panel of claim 1, wherein the second solar cell layer comprises a p-i-n, p-n, n-i-p or n-p configuration in a direction from the first substrate to the second substrate.

8. The solar panel of claim 7, wherein the second solar cell layer comprises two transparent conductive layers, the p-i-n, p-n, n-i-p or n-p configuration is sandwiched between the two transparent conductive layers.

9. The solar panel of claim 1, wherein the transparent intercellular layer comprises SiO, SiC, SiN, SiON, SiOC, or SiCN.

10. The solar panel of claim 1, wherein the transparent intercellular layer has a thickness ranging from about 1 nm to about 10 mm.

11. A multi-terminal solar panel comprising:
a transparent first substrate;
a first solar cell layer disposed on the first substrate and having a first bandgap, the first solar cell layer comprising two first terminal outputs, arranged substantially in parallel with each other, at two opposite edges thereof;
a transparent intercellular layer disposed on the first solar cell layer and exposing the two first terminal outputs;
a second solar cell layer disposed on the transparent intercellular layer and having a second bandgap, the second solar cell layer comprising two second terminal outputs, arranged substantially in parallel with each other, at two opposite edges thereof; and
a transparent second substrate disposed on the second solar cell layer,
wherein the two second terminal outputs are substantially perpendicular to the two first terminal outputs.

12. The solar panel of claim 11, wherein the first bandgap is larger than or the same with the second bandgap.

13. The solar panel of claim 11, further comprising an encapsulant sheet between the second solar cell layer and the transparent second substrate.

14. The solar panel of claim 11, wherein the transparent intercellular layer is an insulator to prevent oxygen and moisture from penetrating the transparent intercellular layer.

15. The solar panel of claim II, wherein the first solar cell layer comprises a p-i-n or p-n configuration in a direction from the first substrate to the second substrate.

16. The solar panel of claim IS, wherein the first solar cell layer comprises two conductive layers, the p-i-n or p-n configuration is sandwiched between the two conductive layers.

17. The solar panel of claim 11, wherein the second solar cell layer comprises a p-i-n, p-n, n-i-p or n-p configuration in a direction from the first substrate to the second substrate.

18. The solar panel of claim 17, wherein the second solar cell layer comprises two conductive layers, the p-i-n, p-n, n-i-p or n-p configuration is sandwiched between the two conductive layers.

19. The solar panel of claim 11, wherein the transparent intercellular layer comprises SiO, SiC, SiN, SiON, SiOC, or SiCN.

20. The solar panel of claim 11, wherein the transparent intercellular layer has a thickness ranging from about 1 nm to about 10 mm.
